(19) United States
(12) Patent Application Publication
(10) Pub. No.: US 2026/0299001 A1
(43) Pub. Date: Oct. 1, 2026

(54) INSULATION FAULT DETECTION DEVICE, ELECTRICAL POWER SUPPLY SYSTEM, AND A METHOD FOR DETECTING AN INSULATION FAULT

(71) Applicant: H55 SA, Sion (CH)

(72) Inventors: David Costes, Bramois (CH); Milan Utvic, Sion (CH); Aurélien Carrupt, St-Pierre-de-Clages (CH)

(21) Appl. No.: 19/478,780

(22) PCT Filed: Apr. 11, 2024
(86) PCT No.: PCT/IB2024/053532

§ 371 Date: Oct. 24, 2025

(30) Foreign Application Priority Data
Apr. 27, 2023 (CH) CH000447/2023

(51) Int. Cl. G01R 31/14; B64D 31/18; G01R 31/00; H02H 7/08

(52) U.S. Cl. CPC G01R 31/14; B64D 31/18; G01R 31/008; H02H 7/08

(57) ABSTRACT

The invention relates to an insulation fault detection device (40) for detecting insulations faults in an electrical power supply system (10, 20, 30) of an electrically or hybrid driven aircraft (100), wherein the electrical power supply system (10, 20, 30) being configured with a DC section and an AC section, wherein the insulation fault detection device (40) includes: an input terminal (DC− , G) configured to receive a measurement signal (V_{DC-}-G) from a sensor, preferably external to the insulation fault detection device (40); an output terminal (S) arranged to provide a signal for indicating an insulation fault; a processing unit (41-43) connected to the input (DC− , G) and output terminal (S) and configured to determine signal properties of the measurement signal (V_{DC-}-G), in which the processing unit (41-43) is configured to set the signal at the output terminal(S) depending on a frequency and/or a slope of an AC component comprised in the measurement signal. The invention also relates to an electrical power supply system (10, 20, 30) for an electrically or hybrid driven aircraft (100), and a method for detecting an insulation fault in the electrical power supply system with the use of the insulation fault detection device (40).

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND OF THE INVENTION

### Technical Domain

The present invention concerns an insulation fault detection device, an electrical power supply system comprising the insulation fault detection device installed in an electrically or hybrid driven aircraft, and a method for detecting an insulation fault in the electrical power supply system using the insulation fault detection device.

### Related Art

Electric and hybrid vehicles have become increasingly significant for the transportation of people and goods. Such vehicles can desirably provide energy efficiency advantages over combustion-powered vehicles and may cause less air pollution than combustion-powered vehicles during operation.

Although the technology for electric and hybrid automobiles has significantly developed in recent years, many of the innovations that enabled a transition from combustion-powered to electric-powered automobiles unfortunately do not directly apply to the development of electric or hybrid aircraft. The functionality of automobiles and the functionality of aircraft are sufficiently different in many aspects so that many of the design elements for electric and hybrid aircraft must be uniquely developed separate from those of electric and hybrid automobiles.

Moreover, any changes to an aircraft's design, such as to enable electric or hybrid operation, also require careful development and testing to ensure safety and reliability. If an aircraft experiences a serious failure during flight, the potential loss and safety risk from the failure may be very high as the failure could cause a crash of the aircraft and pose a safety or property damage risk to passengers or cargo, as well as individuals or property on the ground.

The certification standards for electric or hybrid aircraft are further extremely stringent because of the risks posed by new aircraft designs. Designers of aircraft have struggled to find ways to meet the certification standards and bring new electric or hybrid aircraft designs to market.

In view of these challenges, attempts to make electric and hybrid aircraft commercially viable have been largely unsuccessful. New approaches for making and operating electric and hybrid aircraft thus continue to be desired.

Flying a manned or unmanned aircraft such an airplane can be dangerous. Problems with the aircraft may result in injury or loss of life for passengers in the aircraft or individuals on the ground, as well as damage to goods being transported by the aircraft or other items around the aircraft.

The reliability of systems can be improved with redundant subsystems. Various designs have been suggested in order to replace a faulty subsystem with a backup subsystem. For example, in the context of electric powered object or vehicles, US20171210229 A1 and US20111254502A1 both describe a fault-tolerant battery management system in which the state of battery cells is monitored and/or controlled by redundant battery management systems (BMS), such that a default in one BMS does not prevent the battery from functioning as long as the redundant BMS performs properly. However, if the two BMS are identical, they are more likely to present the same defaults or conception problems, and are also more likely to have failure simultaneously or at short interval. Moreover, those solutions have not been designed with the aim of certification for aircraft; adding additional components increase the complexity of the system and makes the certification even more difficult.

In order to attempt to mitigate potential problems associated with an aircraft, numerous organizations have developed certification standards for ensuring that aircraft designs and operations satisfy threshold safety requirements. The certification standards may be stringent and onerous when the degree of safety risk is high, and the certification standards may be easier and more flexible when the degree of safety risk is low.

As an example, the FAA advisory circular AC 25.1309-1 describes acceptable means for showing compliance with the airworthiness requirements of US Federal Aviation Regulations defines different levels of failure conditions according to their severity: Failure Conditions with no safety effect.
Minor Failure Conditions.
Major Failure Conditions.
Hazardous Failure Conditions must be no more frequent than extremely remote.
Catastrophic Failure Conditions must be extremely improbable.

While airplanes must be designed so that hazardous and catastrophic failure conditions are extremely remote or even extremely improbable, those severe failure conditions must nevertheless be monitored, so that warning signals are sent to the pilot and driver who may attempt to remedy to the condition or try to land the aircraft. The monitoring and warning systems must be reliable and also requires certification.

Such certification standards have unfortunately had the effect of slowing commercial adoption and production of electric or hybrid aircraft. Electrical hybrid aircraft may, for example, utilize new aircraft designs relative to traditional aircraft designs to account for differences in operations of electric or hybrid aircraft versus traditional aircraft. The new designs however may be significantly different from the traditional aircraft designs. These differences may subject the new designs to extensive testing prior to certification. The need for extensive testing can take many resources, time and significantly drive up the ultimate cost of the aircraft.

There is therefore a need for simplified, yet robust, components and systems for an electric powered aircraft that simplify and streamline certifications requirements and reduce the cost and time required to produce a commercially viable electric aircraft.

A matter of concern is especially electrical power supply system for such types of aircraft as they are operated at high system voltages, typically of about 400 V to 800 V, or even higher. Electrical power supply systems designed for such high voltages require a sophisticated insulation system to prevent short circuits or spillovers to other electrical onboards systems in the aircraft. On the other hand, such insulation systems are designed to avoid electrocution of passengers or maintenance personnel when contacting high voltage lines with an insulation fault.

Devices for the detection of insulation breakdowns are known from the prior art. However, such devices are often designed to detect only a few specific insulation faults. Moreover, conventional devices are adapted to detect insulation faults in specific system configurations only, which makes an adaptation to a respective insulation system or electrical power supply system necessary. Specific adaptations contradict the increase of the re-use factor and entail a number of further consequences, such as the need for re-certification, which is a time-consuming and costly process.

The invention, therefore, has the objective of remedying some disadvantages of the prior art. In particular, it is an objective to provide an insulation fault detection device that enables fast and reliable detection of insulation faults in different configurations of electrical power supply systems leading to different fault scenarios. The proposed solution improves the safety of the aircraft sustainably and can omit or at least relief the requirement for re-certification if the insulation fault detection device is used for different configurations of electrical power supply systems.

In addition, an electrical power supply system is disclosed, which makes use of the insulation fault detection device, which is robust and can be flexibly configurated, in particular with respect to the electrical source that is used for supplying the electrical power supply system. This measure can increase the re-use factor significantly.

### Short Disclosure of the Invention

According to a first aspect of the present invention, an insulation fault detection device is disclosed, involving the features recited in claim 1. Further features and embodiments of the insulation fault detection device of the present invention are described in the dependent patent claims.

The invention relates to an insulation fault detection device for detecting insulations faults in an electrical power supply system of an electrically or hybrid driven aircraft, wherein the electrical power supply system being configured with a DC section and an AC section, wherein the insulation fault detection device includes:
an input terminal configured to receive a measurement signal from a sensor, preferably external to the insulation fault detection device;
an output terminal arranged to provide a signal for indicating an insulation fault;
a processing unit connected to the input and output terminal and configured to determine signal properties of the measurement signal, in which the processing unit is configured to set the signal at the output terminal depending on a frequency and/or a slope of an AC component comprised the measurement signal.

The sensor can be a voltage or current sensor, whereas the sensor is configured to convert a voltage or a current apparent in the DC section into a measurement signal which can be determined by the processing unit. The AC section of the electrical power supply system can be electrically insulated from the DC section. The DC section can relate to a DC link of a power converter and the AC section can relate to the output of the power converter, supplying a corresponding load with AC voltages and currents. The load can also be insulated from the DC section.

The expression “depending on a frequency and/or a slope of the measurement signal” can relate to the circumstance that an AC signal can be comprised in the measurement signal having a frequency, an amplitude, and a related slope. The measurement signal as such can have a DC signal character, and the AC signal or AC component can be overlayed onto the DC signal. The processing unit can determine at least one of these properties of the AC signal and can set the signal at the output terminal if one of the determined properties exceeds a predetermined threshold. Alternatively, the processing unit can set the signal at the output terminal if more than one of the determined properties exceeds a threshold.

The processing unit can include digital components, such as a processor, a FPGA circuit, a microcontroller and/or any combination of digital and/or analog circuitry. The voltage measurement signal can be provided in the form or appearance of a voltage signal, a current signal, optical signals, or a digital signal on a communication bus, whereby the signal level can correspond to the level of the potential difference determined. Preferably, the processing unit can be provided in form of an analog circuit. Analog circuits have already been used for decades, and implementing the processing unit with analog circuits can reduce the effort for aircraft certification.

The input terminal is configurated depending on the form or appearance of the measurement signal. To be more specific, in the case the measurement signal is provided via a communication bus, the input terminal can be arranged to be connected to the said communication bus. The output terminal can be arranged to be connected to a communication bus, or in the form of a control output. The signal for indicating an insulation fault can be sent to a safety or higher level control device external to the insulation fault detection device.

The sensor must not necessarily be external to the insulation fault detection device, as it can also be a part of the said device. Under the circumstance that the sensor is part of the insulation fault detection device, then the said sensor can be configured to provide a voltage measurement signal for determining a potential difference between a first electrical potential and the reference potential, wherein the first electrical potential and the reference potential can be external to the insulation fault detection device. In the case of a current sensor, the said sensor can be configurated to convert a current flowing in the electrical supply system into a corresponding measurement signal.

An AC voltage or AC signal can be expressed as a periodic signal, which continuously reverses its direction and can change its magnitude over time. The slope correspondingly describes the direction and the steepness of the change in direction or magnitude of the AC voltage over time. The slope can be positive or negative, depending on the direction in which the AC voltage changes.

In a first embodiment of the first aspect of the invention,
said sensor can be a voltage sensor, and
said measurement signal can be a voltage measurement signal, and
said AC component can be an AC voltage component, wherein the processing unit can be configured to set the signal at the said output terminal upon the detection of the slope of the AC voltage component comprised in the voltage measurement signal.

In a second embodiment of the first aspect of the invention, the AC voltage component comprised in the voltage measurement signal can be a signal having a rectangular shape, wherein the slope can correspond to an edge of the said rectangular signal. Alternatively, the AC voltage component comprised in the voltage measurement signal can be a signal having a sinusoidal, triangular, or sawtooth shape, and the slope can correspond to or express a rising or falling amplitude.

In a third embodiment of the first aspect of the invention, the signal at the output terminal can be set upon the detection of an edge of the said rectangular signal. The edge can be a rising or falling edge. By setting the signal at the output terminal, the insulation fault detection device can signal the detection of the edge, which can indicate to the safety or higher-level control device, external to the insulation fault detection device, that an insulation fault was detected.

In a different embodiment of the first aspect of the invention, the signal at the output terminal can be set upon the detection of a series of edges, wherein the series can comprise more than 3, more than 5, and/or more than 10 edges, but preferably less than 20 edges. The processing unit can be arranged to count the edges. This can include counting the rising or the falling edge only. Alternatively, can the processing unit be configured to count both, the rising and falling edges. Not setting the signal at the output terminal upon the detection of a first edge can be advantageous, as the signalling of false insulation faults can be prevented. Since the AC voltage comprised in the voltage measurement signal can be a periodic signal, the series can have a series of consecutive edges.

In a further embodiment of the first aspect of the invention, the voltage measurement signal can comprise the AC voltage component and a DC voltage component, wherein the processing unit can be configured to be sensitive to the AC voltage component only. Therefore, can the processing unit be configured to process or determine the AC voltage only. The DC voltage component can be comprised in the voltage measurement signal as an offset signal into which the AC voltage is modulated. The amplitude of the offset signal can depend on the DC potential and the reference potential to which the voltage sensor is connected and can also depend on the insulation fault, as different insulation faults can cause variations of the offset signal.

In another embodiment of the first aspect of the invention, the processing unit can comprise a filter connected to the input terminal, wherein the filter can be configured to cancel the DC voltage component comprised in the voltage measurement signal. The filter can be a digital filter or an analog filter circuit and can be a functional part of the processing unit. However, the filter can also be external to the processing unit. By cancelling the DC component, the processing unit can focus on detecting the slope or edges in the voltage measurement signal without needing an offset to detect the slope or edge reliably. Therefore a calibration of the processing unit to adapt to the DC level of the input signal can be omitted.

In a different embodiment of the first aspect of the invention, the filter can be configured as an analog filter. Analog filter circuits suitable to cancel a DC voltage component out of a mixed signal are well known from the prior art. The use of analog filters can reduce the power consumption of the processing unit or the insulation detection fault device, respectively. In addition, as insulation faults are detected by observing differences between two potentials that are insulated by design, it is required that the insulation fault detection device dos not break this isolation. The analog detection circuit can incorporate a galvanic isolation mean (such as a safety capacitor) to respect the isolation requirements between the monitored potentials.

In a further embodiment of the first aspect of the invention, the filter can be configured as a first-order high-pass filter. The filter can employ active analog components, such as amplifiers, and passive components, such as capacitors and resistors. However, the filter can also be embodied as a digital filter in the processing unit. First-order filters can cancel the DC component completely without adding a tremendous complexity to the processing unit or the insulation detection fault device.

Even though the individual embodiments of the first aspect cover different aspects of the invention, some or all embodiments can be combined when it is useful and feasible from a technical standpoint.

According to a second aspect of the present invention, an electrical power supply system for an electrically or hybrid driven aircraft is disclosed. Insulation faults apparent in the electrical power supply system can be permanent, meaning while the electrical power supply system operates, be detected. Some solutions known from the prior art may only allow this possibility during an initialisation phase of the electrical power supply system. Insulation faults appearing during the operation may not be detectable at all.

The electrical power supply system of the second aspect comprises:
the insulation fault detection device as disclosed in the first aspect, including the embodiments thereof;
a voltage sensor;
an electrical source configured with a first and a second output for supplying a DC voltage, the DC voltage having a first and a second DC potential;
a load configured with an input end and an output end, wherein the input end is connected to the first and the second output of the electrical source, and the output end is connected to an AC consumer;
an electric connection permanently connecting one of the DC potentials to a reference potential of the said aircraft, wherein
the reference potential and the aircraft are external to the electrical power supply system, and wherein the electrical source and the load are configured to insulate the DC potentials from each other, wherein
the voltage sensor is electrically connected to one of the DC potentials and the reference potential for determining a potential difference between one of the DC potentials and the reference potential.

The reference potential can be an electrical earth or earth potential of the aircraft, typically the chassis or airframe. The said electrical earth can be used as a well-defined reference potential for all electrical and electronic devices in the aircraft. Electrically conductive surfaces, such as metallic housings of devices, metallic structural elements of the aircraft, etc. can also be connected to the electrical earth, with the aim to protect passengers from high potential differences, also known as touch potential. The DC potential, on the other hand, can be a high DC potential or high DC voltage, such as conventionally supplied by a high-voltage DC source. The terms potential difference and voltage can be used interchangeably in the course of the present disclosure.

As indicated, the DC potential can be electrically insulated from the reference potential, usually by means of an electrical insulation system. This can include but is not limited to functional, basic, supplemental, double, or reinforced insulation according to known safety standards. In addition, the AC consumer (including the connection to the AC consumer) can be electrically insulated from the reference potential and the related DC potentials. The insulation fault detection device can be suitable for detecting faults in all of the before mentioned insulation categories, except an insulation fault between the two DC potentials (DC+, DC−). Different insulation monitoring devices might detect such insulation faults.

One DC potential can be permanently connected to the reference potential with the use of an electric connected. However, the other DC potential can remain insulated from the reference potential and from the one DC potential connected to the reference potential, at least under normal operation. A permanent connection can be required, such that the insulation fault detection device always measures a well-defined potential reference.

The electrical source can be provided in the form of a battery, a fuels cell, or a combination of an electric generator and a rectifier, wherein the rectifier can output the said DC voltage. The load can be any kind of load suitable to convert the electrical supplied by the electrical source into an AC voltage or current, heat, light, or a lower level DC voltage, whereby the list is not exhaustive.

The DC voltage supplied by the electrical source can account for 400V, 600V, 800V, 1000V, 1200V, or even higher than listed. The potential difference between the first and second DC potential can correspond to the DC voltage.

The electrical power supply system can comprise a DC section, which can include the electrical source and the load and the connections therebetween, and an AC section, which can contain the AC consumer and the connection to the output end of the load. As said, the DC and AC sections can be electrically insulated from each other.

In a first embodiment of the second aspect of the invention, the electrical source can be configured with a third output and can provide a third DC potential, wherein the third DC potential can range between the first and the second DC potential. Preferably, the third DC potential can be a mid-point potential, ranging between the first and second DC potential, and thus can divide the potential difference between the first and second DC potential into two halves. Suppose the potential difference between the first and second DC potential accounts to 1000V, then the potential difference measured from the first DC potential to the third DC potential can account for 500V, and measured from the third DC potential to the second DC potential can account for 500V.

In a second embodiment of the second aspect of the invention, the electric connection can be arranged to permanently connect the third DC potential to the reference potential. Alternatively, the electric connection can be arranged to reference the third DC potential to the reference potential. By referencing the third DC potential to the reference potential, the first and second DC potentials automatically become referenced to the reference potential.

In a third embodiment of the second aspect of the invention, the electric connection can comprise an impedance, wherein the impedance can be configured with an ohmic resistance greater than 400 kn, or greater than 1 MO, or equal to 1 MO. This can prevent a high current from circulating in the electric connection in case of an insulation fault.

In a further embodiment of the second aspect of the invention, the load can comprise a motor controller and a motor for propelling the aircraft, wherein an input end of the motor controller can correspond to the input end of the load, and wherein the AC consumer can correspond to the motor connected to the output end. The motor can be configured as an induction or synchronous machine or any variation thereof.

In another embodiment of the second aspect of the invention, the motor controller can comprise a switch configured to interrupt the connection between the input end of the motor controller and the electrical source. The switch can be provided as a high-power contactor, suitable to provide safe insulation between the electrical source and the input end of the motor controller. The switch can be opened suppose an insulation fault has been detected by the insulation fault detection device, preferably in the motor controller or in the motor connected to the motor controller. Catastrophic operational scenarios can be prevented by interrupting the connection if an insulation fault is detected by the insulation fault detection device because the flow of energy to the motor controller and the motor is suspended.

In a different embodiment of the second aspect of the invention, the motor controller can comprise a DC link connected to the first and second DC potential at the input end, wherein the DC link can comprise a series connection of a first and a second capacitor with a center tap, wherein the center tap can be connected to the reference potential via a further electrical connection. Emissions, such as electromagnetic interferences, can be reduced by connecting the center tap to the reference potential. This can be, in many cases desirable, for instance, to prevent the disturbance of other electronic devices comprised in the aircraft.

Even though the individual embodiments of the second aspect cover different aspects of the invention, some or all embodiments can be combined when it is useful and feasible from a technical standpoint.

According to a third aspect of the present invention, a method for detecting an insulation fault in the electrical power supply system according to the second aspect of the invention, including the embodiments thereof and using the insulation fault detection device according to the first aspect, including the embodiments thereof is disclosed.

The method of the third aspect comprises the steps of:
measuring the potential difference between the one DC potential and the reference potential for obtaining a voltage measurement signal;
detecting the slope of the AC voltage component comprised in the voltage measurement signal;
signalling the detection of the slope for indicating an insulation fault.

In a first embodiment of the third aspect of the invention, the method can comprise the step of cancelling the DC voltage component comprised in the voltage measurement signal. Again, and as indicated in the second aspect of the invention, this can be advantageous to primarily focus the detection of an insulation fault to the AC signal and thereby omitting a (re)adaptation of the processing unit to the individual installation situation of the power supply system, by specifically setting an offset.

In a second embodiment of the third aspect of the invention, the AC voltage component comprised in the voltage measurement signal can be the signal having a rectangular shape, wherein the slope can correspond to the edge of the said rectangular signal.

In a third embodiment of the third aspect of the invention, the signalling can be carried out upon the detection of the edge of the said rectangular signal.

In a further embodiment of the third aspect of the invention, the signaling can be carried out upon the detection of a series of edges, wherein the series can comprise more than 3, more than 5, and/or more than 10 edges, but preferably less than 20 edges. The upper limit might be set not to dilute the detection accuracy.

Even though the individual embodiments of the third aspect cover different aspects of the invention, some or all embodiments can be combined when it is useful and feasible from a technical standpoint.

### Short Description of the Drawings

Exemplar embodiments of the invention are disclosed in the description and illustrated by the drawings in which:

### BRIEF DESCRIPTION OF THE DRAWINGS

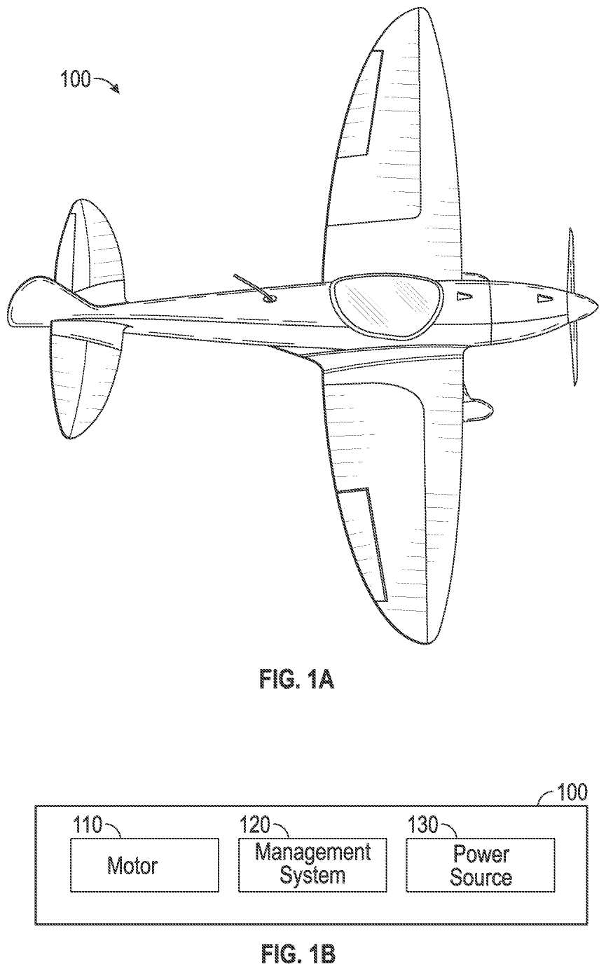

FIG. 1A illustrates an aircraft, such as an electric or hybrid aircraft;

FIG. 1B illustrates a simplified block diagram of an aircraft;

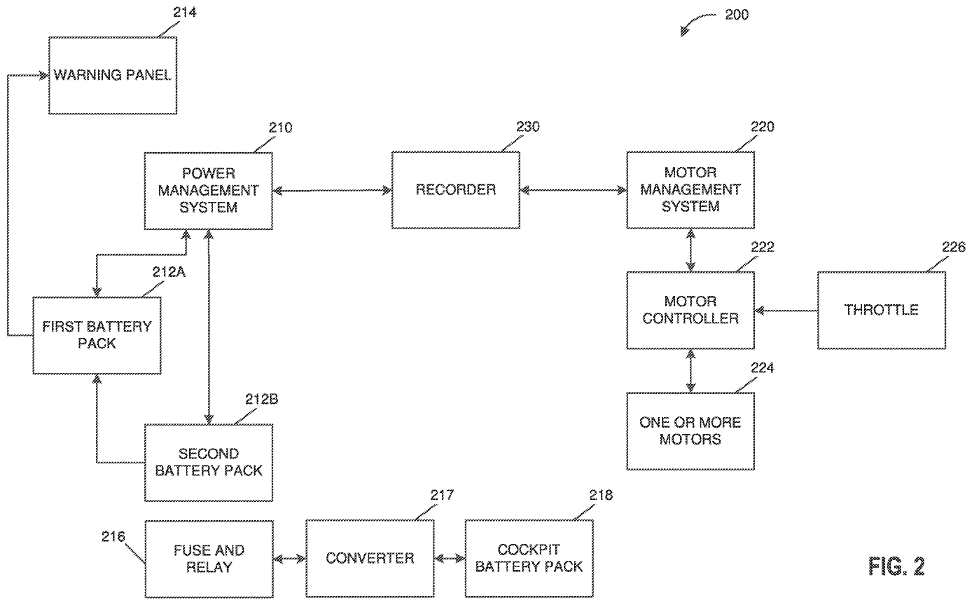

FIG. 2 illustrates management systems for operating an aircraft;

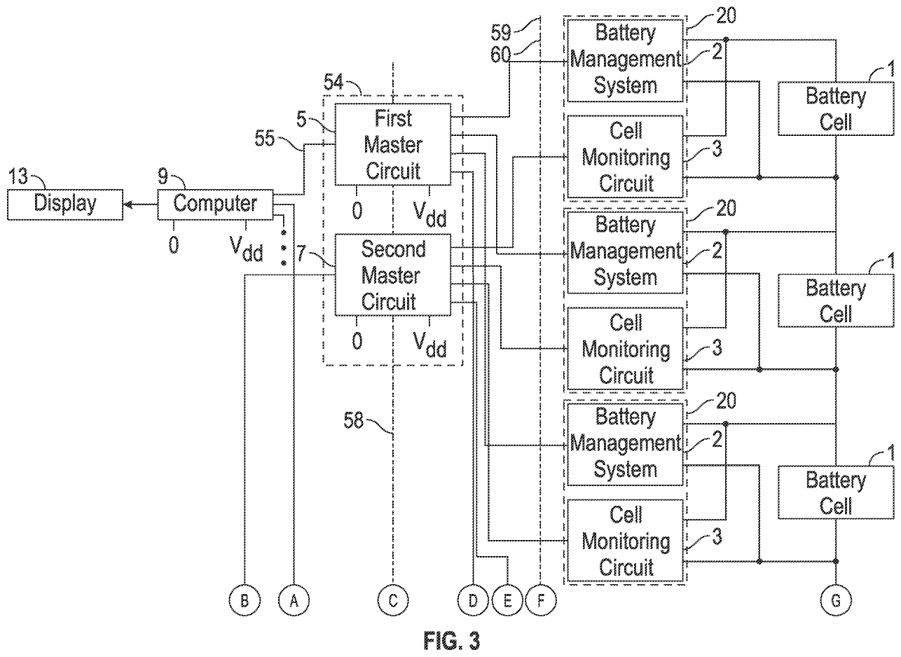

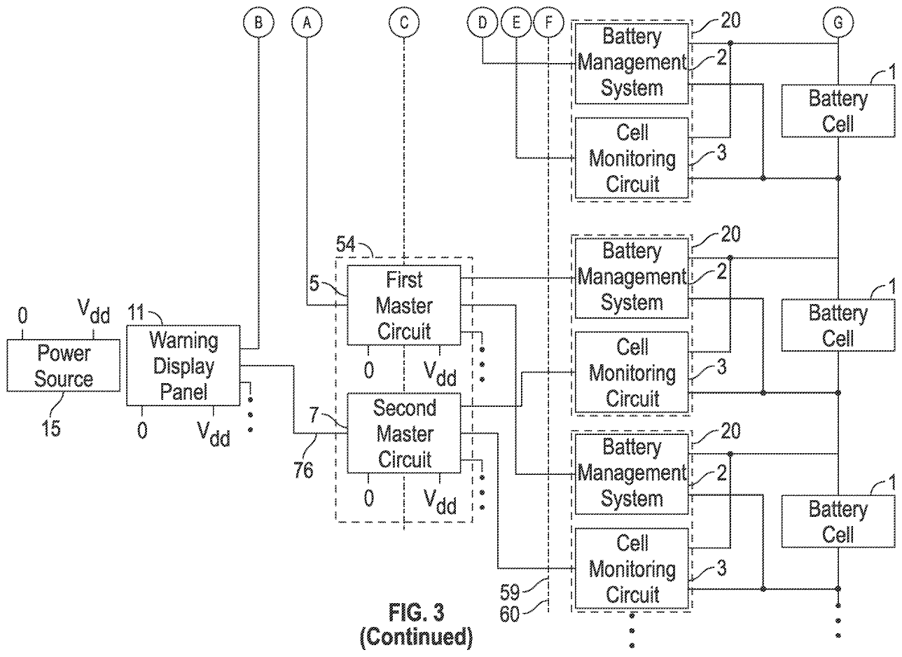

FIG. 3 illustrates an battery monitoring system for an aircraft;

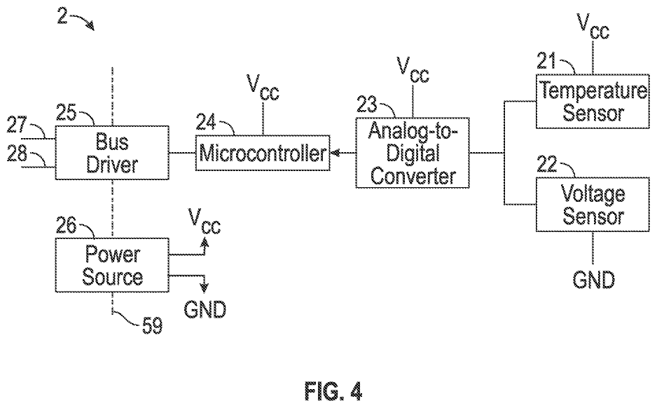

FIG. 4 illustrates an implementation of battery monitoring circuits;

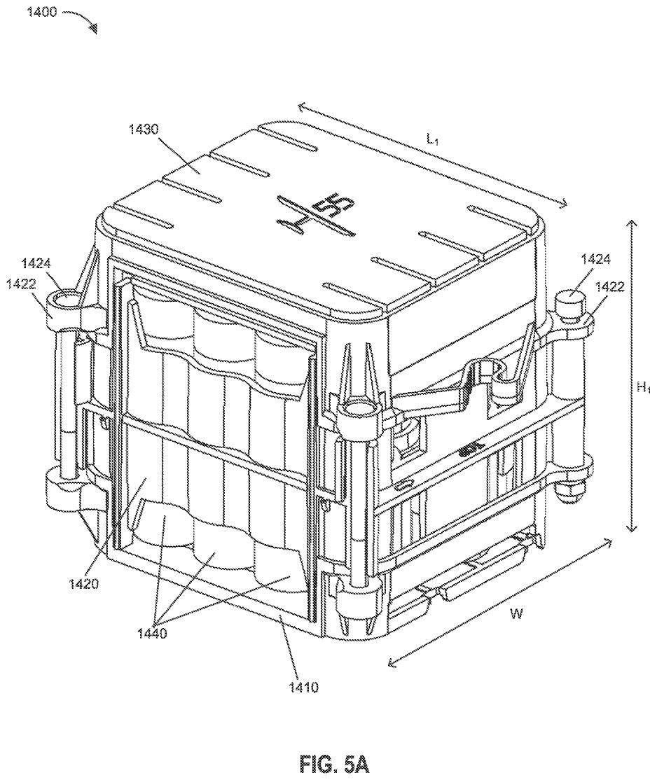

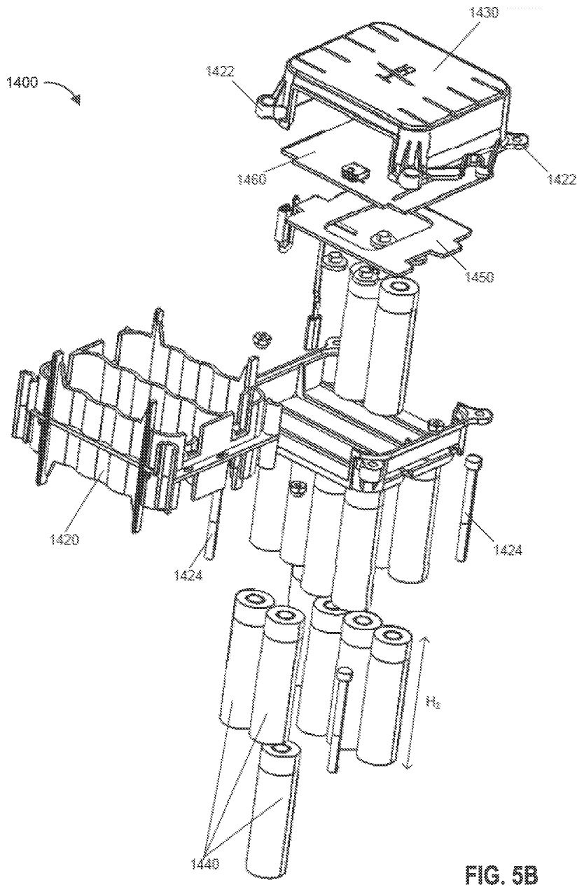

FIGS. 5A and 5B illustrate a battery module usable in an aircraft;

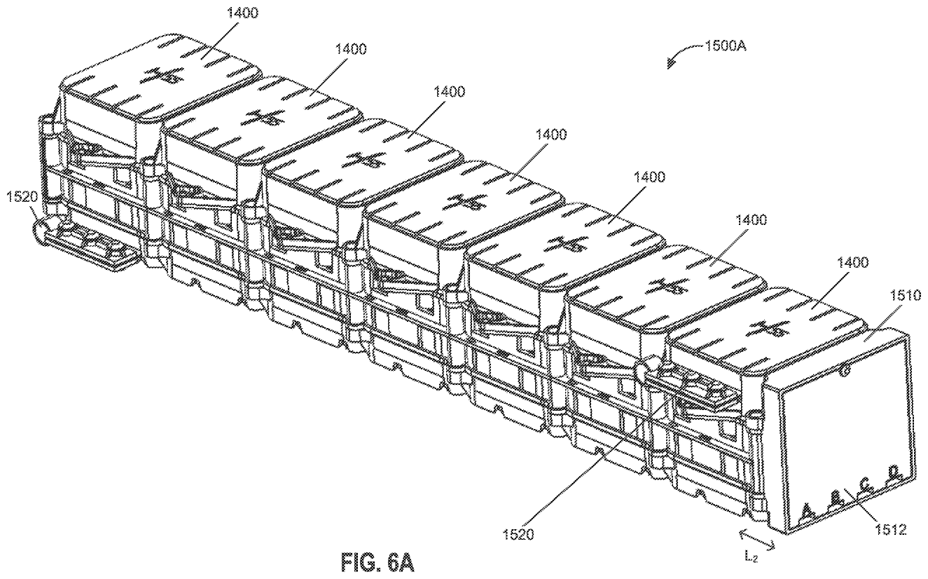

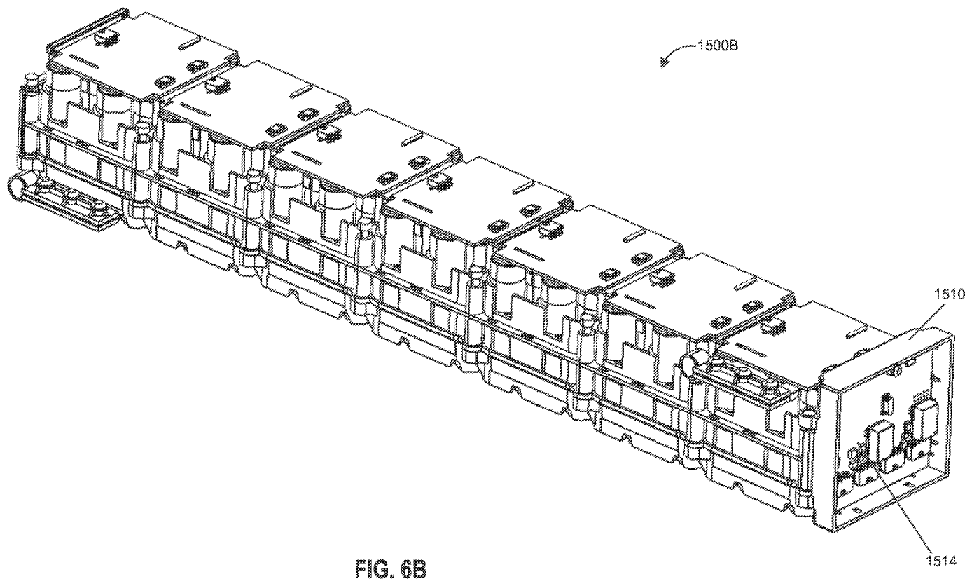

FIGS. 6A and 6B illustrate a power source formed of multiple battery modules;

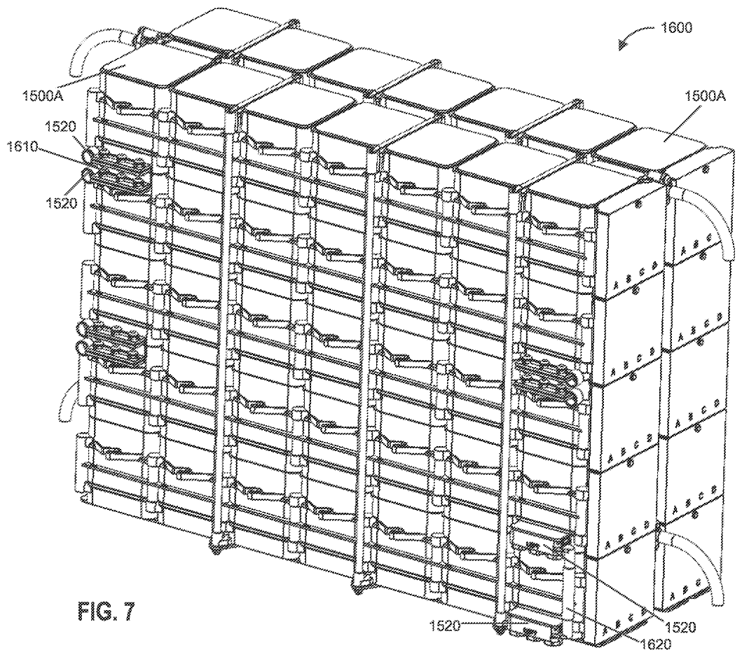

FIG. 7 illustrates multiple power sources arranged and connected for powering an aircraft;

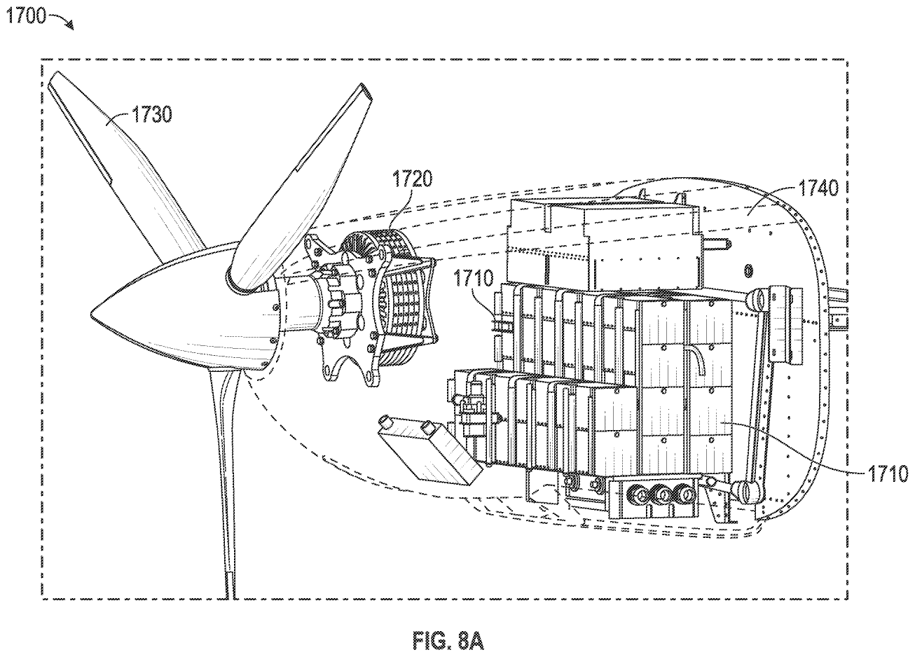

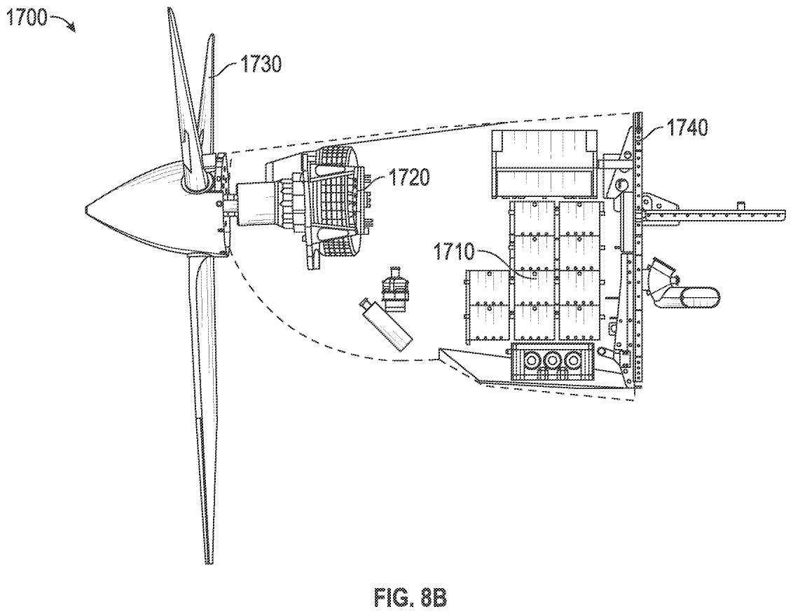

FIGS. 8A and 8B illustrate multiple power sources positioned in a nose of an aircraft for powering the aircraft;

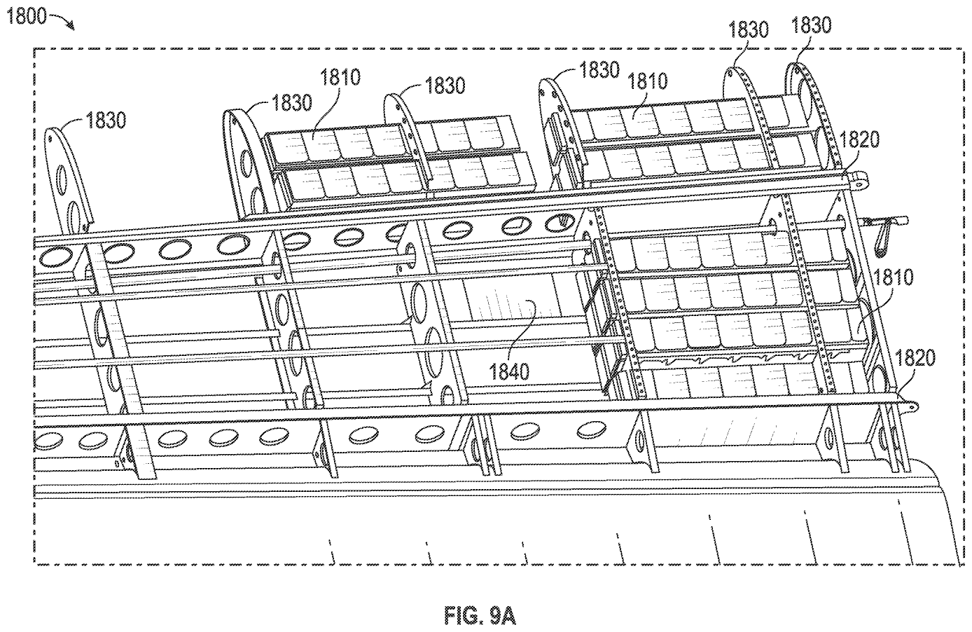

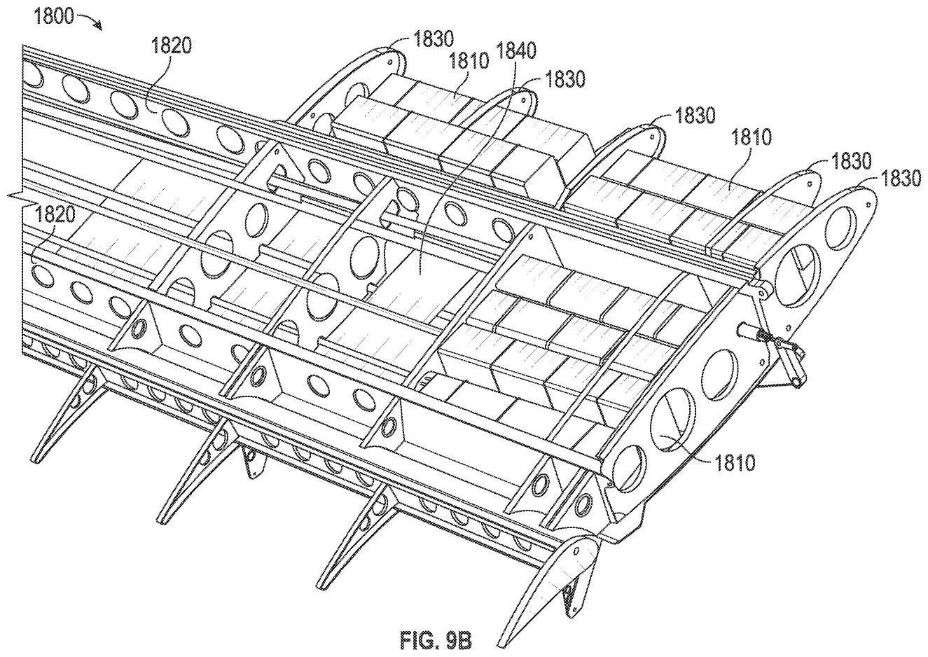

FIGS. 9A and 9B illustrate multiple power sources positioned in a wing of an aircraft for powering the aircraft;

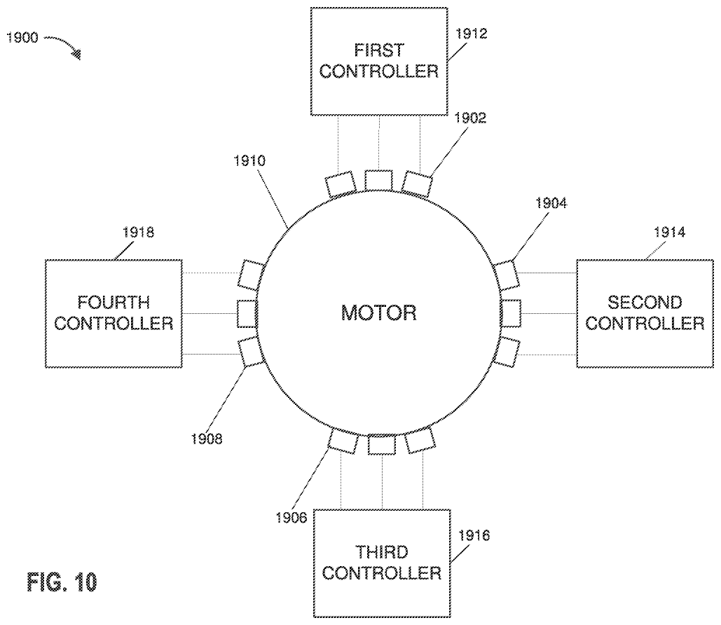

FIG. 10 illustrates a motor with multiple field coils;

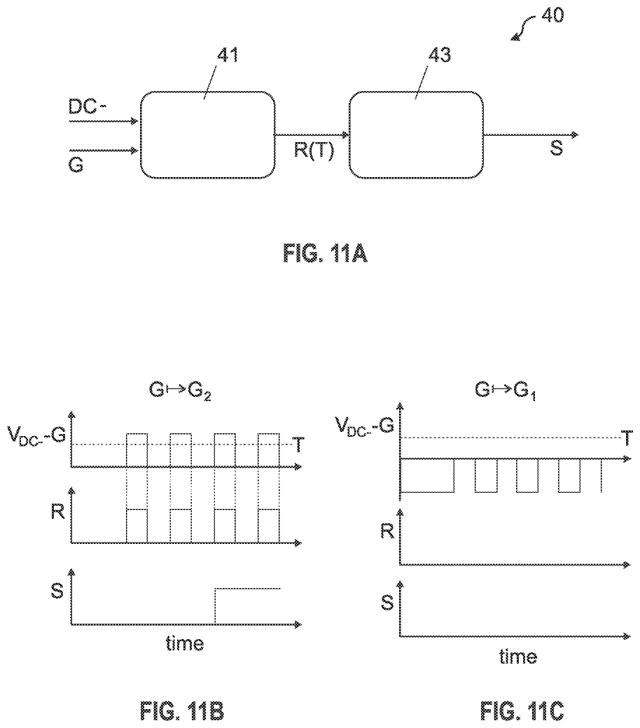

FIGS. 11A to 11C illustrate an insulation fault detection device and related signals according to the prior art;

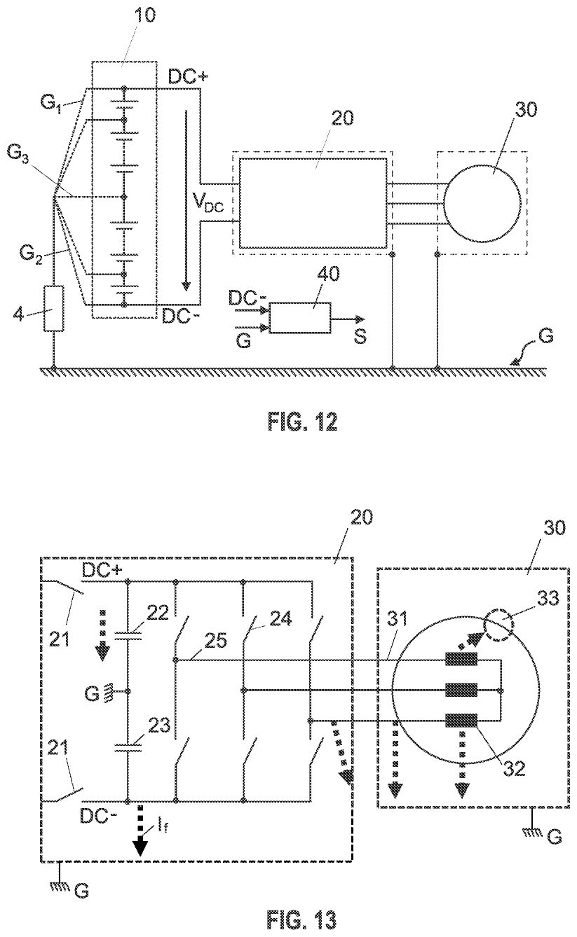

FIG. 12 illustrates an electrical power supply system in the form of a propulsion system and includes an insulation fault detection device according to the invention;

FIG. 13 illustrates insulation fault scenarios in a motor controller and a motor connected thereto; and

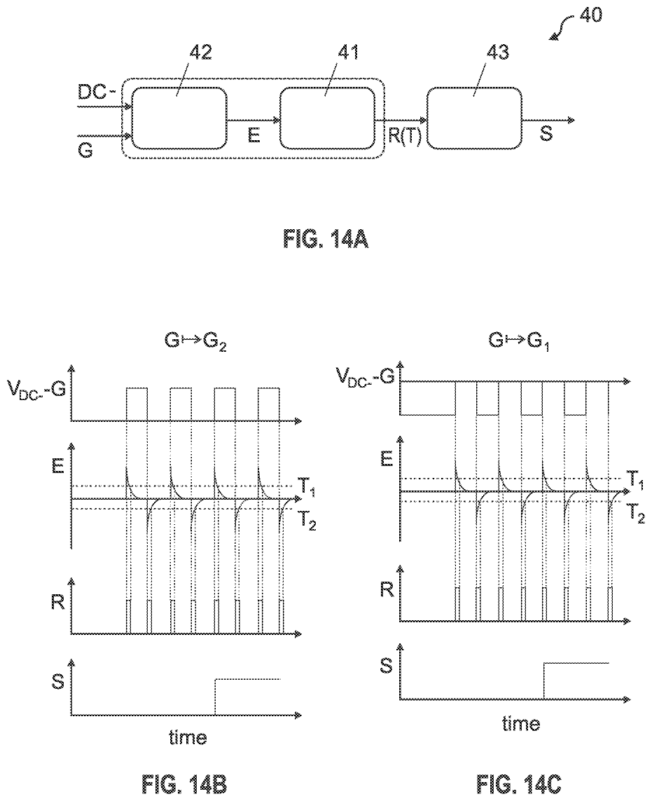

FIGS. 14A to 14C illustrate an insulation fault detection device and related signals according to the invention.

### EXAMPLES OF EMBODIMENTS OF THE PRESENT INVENTION

### System Overview

FIG. 1A illustrates an aircraft 100, such as an electric or hybrid aircraft, and FIG. 1B illustrates a simplified block diagram of the aircraft 100. The aircraft 100 includes a motor 110, a management system 120, and a power source 130. The motor 110 can be used to propel the aircraft 100 and cause the aircraft 100 to fly and navigate. The management system 120 can control and monitor the components (equipment) of the aircraft 100, such as the motor 110 and the power source 130. The power source 130 can power the motor 110 to drive the aircraft 100 and power the management system 120 to enable operations of the management system 120. The management system 120 can include one or more motor controllers as well as other electronic circuitry for controlling and monitoring various components of the aircraft 100.

FIG. 2 illustrates components 200 of an aircraft, such as the aircraft 100 of FIGS. 1A and 1B. The components 200 can include a power management system 210, a motor management system 220, and a recorder 230, as well as a first battery pack 212A, a second battery pack 212B, a warning panel 214, a fuse and relay 216, a converter 217, a cockpit battery pack 218, a motor controller 222, one or more motors 224, and a throttle 226.

The power management system 210, the motor management system 220, and the recorder 230 can monitor communications on a communication bus, such as a controller area network (CAN) bus, and communicate via the communication bus. The first battery pack 212A and the second battery pack 212B can, for instance, communicate on the communication bus enabling the power management system 210 to monitor and control the first battery pack 212A and the second battery pack 212B. As another example, the motor controller 222 can communicate on the communication bus enabling the motor management system 220 to monitor and control the motor controller 222.

The recorder 230 can store some or all data communicated (such as component status, temperature, or over/undervoltage information from the components or other sensors) on the communication bus to a memory device for later reference, such as for reference by the power management system 210 or the motor management system 220 or for use in troubleshooting or debugging by a maintenance worker. The power management system 210 and the motor management system 220 can each output or include a user interface that presents status information and permits system configurations. The power management system 210 can control a charging process (for instance, a charge timing, current level, or voltage level) for the aircraft when the aircraft is coupled to an external power source to charge a power source of the aircraft, such as the first battery pack 212A or the second battery pack 212B.

The warning panel 214 can be a panel that alerts a pilot or another individual or computer to an issue, such as a problem associated with a power source like the first battery pack 212A. The fuse and relay 216 can be associated with the first battery pack 212A and the second battery pack 212B and usable to transfer power through a converter 217 (for example, a DC− DC converter) to a cockpit battery pack 218. The fuse and relay 216 can protect one or more battery poles of the first battery pack 212A and the second battery pack 212B from a short or overcurrent. The cockpit battery pack 218 may supply power for the communication bus.

The motor management system 220 can provide control commands to the motor controller 222, which can in turn be used to operate the one or more motors 224. The motor controller can include an inverter for generating AC currents that are needed for operating the one or more motors. The motor controller 222 may further operate according to instructions from the throttle 226 that may be controlled by a pilot of the aircraft. The one or more motors can include an electric brushless motor.

The power management system 210 and the motor management system 220 can execute the same or similar software instructions and may perform the same or similar functions as one another. The power management system 210, however, may be primarily responsible for power management functions while the motor management system 220 may be secondarily responsible for the power management functions. Similarly, the motor management system 220 may be primarily responsible for motor management functions while the power management system 210 may be secondarily responsible for the motor management functions. The power management system 210 and the motor management system 220 can be assigned respective functions, for example, according to system configurations, such as one or more memory flags in memory that indicate a desired functionality. The power management system 210 and the motor management system 220 may include the same or similar computer hardware.

The power management system 210 can automatically perform the motor management functions when the motor management system 220 is not operational (such as in the event of a rebooting or failure of the motor management system 220), and the motor management system 220 can automatically perform the power management functions when the power management system 210 is not operational (such as in the event of rebooting or failure of the power management system 210). Moreover, the power management system 210 and the motor management system 220 can take over the functions from one another without communicating operation data, such as data about one or more of the components being controlled or monitored by the power management system 210 and the motor management system 220. This can be because both the power management system 210 and the motor management system 220 may be consistently monitoring communications on the communication bus to generate control information, but the control information may be used if the power management system 210 and the motor management system 220 has primary responsibility but not if the power management system 210 and the motor management system 220 does not have primary responsibility. Additionally or alternatively, the power management system 210 and the motor management system 220 may access data stored by the recorder 230 to obtain information usable to take over primary responsibility.

### System Architecture

Electric and hybrid aircraft (rather than aircraft powered during operation by combustion) have been designed and manufactured for decades. However, electric and hybrid aircraft have still not yet become widely used for most transport applications like carrying passengers or goods.

This failure to adopt may be in large part because designing an aircraft that is sufficiently safe to be certified by certification authorities may be very difficult. The certification of prototypes may moreover not be sufficient to certify for commercial applications. Instead, a certification of each individual aircraft and its components may be required.

This disclosure provides at least some approaches for constructing electric powered aircraft from components and systems that have been designed to pass certification requirements so that the aircraft itself may pass certification requirements and proceed to active commercial use.

Certification requirements can be related to a safety risk analysis. A condition that may occur with an aircraft or its components can be assigned to one of multiple safety risk assessments, which may in turn be associated with a particular certification standard. The condition can, for example, be catastrophic, hazardous, major, minor, or no safety effect. A catastrophic condition may be one that likely results in multiple fatalities or loss of the aircraft. A hazardous condition may reduce the capability of the aircraft or the operator ability to cope with adverse conditions to the extent that there would be a large reduction in safety margin or functional capability crew physical distress/excessive workload such that operators cannot be relied upon to perform required tasks accurately or completely or serious or fatal injury to small number of occupants of aircraft (except operators) or fatal injury to ground personnel or general public. A major condition can reduce the capability of the aircraft or the operators to cope with adverse operating condition to the extent that there would be a significant reduction in safety margin or functional capability, significant increase in operator workload, conditions impairing operator efficiency or creating significant discomfort physical distress to occupants of aircraft (except operator), which can include injuries, major occupational illness, major environmental damage, or major property damage. A minor condition may not significantly reduce system safety such that actions required by operators are well within their capabilities and may include a slight reduction in safety margin or functional capabilities, slight increase in workload such as routine flight plan changes, some physical discomfort to occupants or aircraft (except operators), minor occupational illness, minor environmental damage, or minor property damage. A no safety effect condition may be one that has not effect on safety.

An aircraft can be designed so that different monitoring and warning subsystems, such as battery monitoring circuits, of the aircraft are constructed to have a robustness corresponding to their responsibilities and any related certification standards, as well as potentially any subsystem redundancies.

Where a potential failure of the responsibilities of a monitoring and warning subsystem would likely be catastrophic, the subsystem can be designed to be simple and robust and thus may be able to satisfy difficult certification standards. The subsystem, for instance a battery, motor or motor controller monitoring circuit, can be composed of non-programmable, non-stateful components (for example, analog or non-programmable combinational logic electronic components) rather than programmable components (for example, a processor, a field programmable gate array (FPGA), or a complex programmable logic device (CPLD)) or stateful components (for example, sequential logic electronic components) and activate indicators such as lights rather than more sophisticated displays.

On the other hand, where either (i) a monitoring and warning subsystem (such as a battery monitoring circuit, a motor monitoring circuit or a motor controller monitoring circuit) of an aircraft monitors a parameter redundantly with another subsystem of the aircraft that is composed of non-programmable, non-stateful components or (ii) a potential failure of the responsibilities of such a monitoring and warning subsystem would likely be less than catastrophic, or less than hazardous, the subsystem can be at least partly digital and designed to be complicated, feature-rich, and easier to update and yet able to satisfy associated certification standards. Such a subsystem can, for instance, include a processor or other programmable components that outputs information to a sophisticated display for presentation.

In some implementations, some or all catastrophic conditions monitored for by an aircraft can be monitored for with at least one monitoring and warning subsystem that does not include a programmable component or a stateful component because certifications for programmable components or stateful components may demand statistical analysis of the responsible subsystems, which can be very expensive and complicated to certify. Such implementations can moreover be counterintuitive at least because an electric or hybrid aircraft may include one or more relatively advanced programmable or stateful components to enable operation of the electric or hybrid aircraft, so the inclusion of one or more subsystems in the aircraft that does not include any programmable components or any stateful components may be unexpected because the one or more relatively advanced programmable or stateful components may be readily and easily able to implement the functionality of the one or more subsystems that does not include any programmable components or any stateful components.

An aircraft monitoring system can include a first monitoring and warning subsystem and a second monitoring and warning subsystem. The second subsystem, such as a second battery monitoring circuit, can be supported by an aircraft housing and include non-programmable, non-stateful components, such as analog or non-programmable combinational logic electronic components. The non-programmable, non-stateful components can monitor a component (such as battery cells in a battery pack) supported by the aircraft housing and output a second alert to notify of a catastrophic condition associated with the component. The non-programmable, non-stateful components can, for instance, activate an indicator or an audible alarm for a passenger aboard the housing to output the first alert. The indicator or audible alarm may remain inactive unless the indicator is outputting the first alert. Additionally or alternatively, the non-programmable, non-stateful components can output the second alert to a computer aboard or remote from the aircraft (for example, to automatically trigger actions to attempt to respond to or address the catastrophic condition, such as to stop charging or activate a fire extinguisher, a parachute, or an emergency landing procedure or other emergency response feature) or an operator of the aircraft via a telemetry system. The non-programmable, non-stateful components may, moreover, not be able to control the component or at least control certain functionality of the component, such as to control a mode or trigger an operation of the component.

The first subsystem, such as a first battery monitoring circuit, can be supported by the aircraft housing and include a processor (or another programmable or stateful component), as well as a communication bus. The processor can monitor the component from communications on the communication bus and output a first alert to notify of a catastrophic condition or a less than catastrophic condition associated with the component. The processor can, for instance, activate an indicator or audible alarm for a passenger aboard the housing to output the first alert. Additionally or alternatively, the processor can output the first alert to a computer aboard or remote from the aircraft (for example, to automatically trigger actions to attempt to address the catastrophic condition, such as to activate a fire extinguisher, a parachute, or an emergency landing procedure) or an operator of the aircraft via a telemetry system. The processor may control the component.

The non-programmable, non-stateful components of the second subsystem additionally may not be able to communicate via the communication bus. It may not include any programmable communication circuit for allowing communication via such a bus.

An example of such a design and its benefits are next described in the context of battery management systems. Notably, the design can be additionally or alternatively applied to other systems of a vehicle that perform functions other than battery management, such as motor and motor control.

FIG. 3 illustrates a battery monitoring system. This system can be used in an electric vehicle, such as an electric aircraft, a large size drone or unmanned aerial vehicle, an electric car, or the like, to monitor the state of battery cells 1 in one of multiple battery packs and report this state or generate warning signals in case of dysfunctions.

The battery cells 1 can be connected in series or in parallel to deliver a desired voltage and current. FIG. 3 shows serially connected battery cells. The total number of battery cells 1 may exceed 100 cells in an electric aircraft. Each of the battery cells 1 can be made up of multiple elementary battery cells in parallel.

A first battery monitoring circuit can control and monitor the state of each battery cell 1. The first battery management circuit can include multiple BMSs 2, each of the BMSs 2 managing and controlling one of the battery cells 1. The BMSs 2 can each be made up of an integrated circuit (for instance, a dedicated integrated circuit) mounted on one printed circuit board (PCB) of the PCBs 20. One of the PCBs 20 can be used for each of the battery cells 1 or for a group of battery cells. FIG. 4 illustrates example components of one of the BMSs 2.

The control of a battery cell can include control of its charging and discharge cycles, preventing a battery cell from operating outside its safe operating area, or balancing the charge between different cells.

The monitoring of one of the battery cells 1 by one of the BMSs 2 can include measuring parameters of the one of the battery cells 1, to detect and report its condition and possible dysfunctions. The measurement of the parameters can be performed with battery cell parameter sensors, which can be integrated in the one of the BMSs 2 or connected to the one of the BMSs 2. Examples of such parameter sensors can include a temperature sensor 21, a voltage sensor 22, or a current sensor. An analog-to-digital converter 23 can convert the analog values measured by one or more of the parameter sensors into multivalued digital values, for example, 8 or 16 bits digital parameter values. A microcontroller 24, which can be part of each of the BMSs 2, can compare the values with thresholds to detect when a battery cell temperature, battery cell voltage, or battery cell current is outside a range.

The BMSs 2 as slaves can be controlled by one of multiple first master circuits 5. In the example of FIG. 3, each of the first master circuits 5 can control four of the BMSs 2. Each of the first master circuits 5 can control eight of the BMSs 2, or more than eight of the BMSs 2. The first master circuits 5 can control more BMS and more battery cells in yet other implementations. The first master circuits 5 can be connected and communicate over a digital communication bus 55.

The first master circuits 5 can also be connected to a computer 9 that collects the various digital signals and data sent by the first master circuits 5, and may display information related to the battery state and warning signals on a display 13, such as a matrix display. The display 13 may be mounted in the vehicle's cockpit to be visible by the vehicle's driver or pilot. Additionally or alternatively, the computer 9 can output the information to a computer remote from the aircraft or to control operations of one or more components of the aircraft as described herein.

The BMSs 2 can be connected to the first master circuits 5 over a digital communication bus, such as a CAN bus. A bus driver 25 can interface the microcontroller 24 with the digital communication bus and provide a first galvanic isolation 59 between the PCBs 20 and the first master circuits 5. In one example, the bus drivers of adjacent BMSs 2 can be daisy chained. For example, as shown in FIG. 4, the bus driver 25 is connected to the bus driver 27 of the previous BMS and to the bus driver 28 of the next BMS.

Each of the BMSs 2 and their associated microcontrollers can be rebooted by switching its power voltage Vcc. The interruption of Vcc can be controlled by the first master circuits 5 over the digital communication bus and a power source 26.

FIG. 3 further illustrates a second battery monitoring circuit, which can be redundant of the first battery monitoring circuit. This second battery monitoring circuit may not manage the battery cells 1; for example, the second battery monitoring circuit may not control charge or discharge cycles of the battery cells 1. The function of the second battery monitoring circuit can instead be to provide a separate, redundant monitoring of each of the battery cells 1 in the battery packs, and to transmit those parameters or warning signals related to those parameters, such as to the pilot or driver or a computer aboard or remote from the aircraft as described herein. The second battery monitoring circuit can monitor the state of each of the battery cells 1 independently from the first battery monitoring circuit. The second battery monitoring circuit can include one of multiple cell monitoring circuits 3 for each of the battery cells. The parameters or warning signals may moreover, for example, be used by the second battery monitoring circuit to stop charging (for instance, by opening a relay to disconnect supply of power) of one or more battery cells when the one or more battery cells may be full of energy and a computer of the aircraft continues to charge the one or more battery cells.

### Motor and Battery System

Battery packs including multiple battery cells, such as lithium-ion cells, can be used in electric cars, electric aircraft, and other electric self-powered vehicles. The battery cells can be connected in series or in parallel to deliver an appropriate voltage and current.

In electrically driven aircraft, the battery packs can be chosen to fulfil the electrical requirements for various flight modes. During short time periods like take off, the electrical motor can utilize a relatively high power. During most of the time, such as in the standard flight mode, the electrical motor can utilize a relatively lower power, but may consume a high energy for achieving long distances of travel. It can be difficult for a single battery to achieve these two power utilizations.

The use of two battery packs with different power or energy characteristics can optimize the use of the stored energy for different flight conditions. For example, a first battery pack can be used for standard flight situations, where high power output may not be demanded, but a high energy output may be demanded. A second battery pack can be used, alone or in addition to the first battery pack, for flight situations with high power output demands, such as take-off manoeuvring.

An electrical powering system can charge the second battery pack from the first battery pack. This can allow recharging of the second battery pack during the flight, subsequent to the second battery pack being used in a high power output demanding flight situation. Therefore, the second battery pack can be small, which can save space and weight. In addition, this can allow different battery packs for different flight situations that optimize the use of the battery packs.

The electrical powering system can also charge the second battery pack by at least one motor which works as generator (the motor may also accordingly be referred to as a transducer). This can allow recharging of the second battery pack during the flight or after the second battery pack has been used in a high power output demanding flight situation. Therefore, the second battery pack can be small, which can save space and weight. In addition, the different battery packs can allow the recovery of braking energy. Braking energy during landing or sinking recovered by a generator motor can create high currents which may not be recovered by battery packs used for traveling long distances. By using a second battery pack suitable for receiving high power output in a short time, more braking energy can be recovered via the second battery pack than the first battery pack, for example.
includes a supercapacitor. Because supercapacitors can receive and output large instantaneous power or high energy in a short duration of time, the third battery pack can further improve the electrical powering system in some instances. A supercapacitor may, for example, have a capacitance of 0.1 F, 0.5 F, 1 F, 5 F, 10 F, 50 F, 100 F, or greater or within a range defined by one of the preceding capacitance values.

FIGS. 8 to 13 illustrate multiple electrical power systems.

FIG. 8 shows an electrical powering system that includes a first battery pack 91, a second battery pack 92, a circuit 90, and at least one motor 94.

### Modular Battery System

The power sources in an electric or hybrid aircraft can be modular and distributed to optimize a weight distribution or select a center of gravity for the electric or hybrid aircraft, as well as maximize a use of space in the aircraft. Moreover, the batteries in an electric or hybrid aircraft can desirably be designed to be positioned in place of a combustion engine so that the aircraft can retain a similar shape or structure to a traditional combustion powered aircraft and yet may be powered by batteries. In such designs, the weight of the batteries can be distributed to match that of a combustion engine to enable the electric or hybrid aircraft to fly similarly to the traditional combustion powered aircraft.

FIG. 5A illustrates a battery module 1400 usable in an aircraft, such as the aircraft 100 of FIGS. 1A and 18. The battery module 1400 can include a lower battery module housing 1410, a middle battery module housing 1420, an upper battery module housing 1430, and a multiple battery cells 1440. The multiple battery cells 1440 can together provide output power for the battery module 1400. The lower battery module housing 1410, the middle battery module housing 1420, or the upper battery module housing 1430 can include slots, such as slots 1422, that are usable to mechanically couple the lower battery module housing 1410, the middle battery module housing 1420, or the upper battery module housing 1430 to one another or to another battery module. Supports, such as supports 1424 (for example, pins or locks), can be placed in the slots to lock the lower battery module housing 1410, the middle battery module housing 1420, or the upper battery module housing 1430 to one another or to another battery module.

The battery module 1400 can be constructed so that the battery module 1400 is evenly cooled by air. The multiple battery cells 1440 can include 16 total battery cells where the battery cells are each substantially shaped as a cylinder. The lower battery module housing 1410, the middle battery module housing 1420, or the upper battery module housing 1430 can be formed of or include plastic and, when coupled together, have an outer shape substantially shaped as a rectangular prism. The lower battery module housing 1410, the middle battery module housing 1420, or the upper battery module housing 1430 can together be designed to prevent a fire in the multiple battery cells 1440 from spreading outside of the battery module 1400.

The battery module 1400 can have a length of L1, a width of W, and a height of H1. The length of L1, the width of W, or the height of H1 can each be 50 mm, 65 mm, 80 mm, 100 mm, 120 mm, 150 mm, 200 mm, 250 mm or within a range defined by two of the foregoing values or another value greater or less than the foregoing values.

FIG. 5B illustrates an exploded view of the battery module 1400 of FIG. 5A. In the exploded view, a plate 1450 and a circuit board assembly 1460 of the battery module 1400 is shown. The plate 1450 can be copper and may electrically connect the multiple battery cells 1440 in parallel with one another. The plate 1450 may also distribute heat evenly across the multiple battery cells 1440 so that the multiple battery cells 1440 age at the same rate. The circuit board assembly 1460 may transfer power from or to the multiple battery cells 1440, as well as include one or more sensors for monitoring a voltage or a temperature of one or more battery cells of the multiple battery cells 1440. The circuit board assembly 1460 may or may not provide galvanic isolation to the battery module 1400 with respect to any components that may be electrically connected to the battery module 1400. Each of the multiple battery cells 1440 can have a height of H2, such as 30 mm, 50 mm, 65 mm, 80 mm, 100 mm, 120 mm, 150 mm or within a range defined by two of the foregoing values or another value greater or less than the foregoing values.

FIG. 6A illustrate a power source 1500A formed of multiple battery modules 1400 of FIGS. 14A and 148. The multiple battery modules 1400 of the power source 1500A can be mechanically coupled to one another. A first side of one battery module 1400 can be mechanically coupled to a first side of another battery module 1400, and a second side of the one battery module 1400 that is opposite the first side can be mechanically coupled to a first side of yet another battery module 1400. The multiple battery modules 1400 of the power source 1500A can be electrically connected in series with one another. As illustrated in FIG. 6A, the power source 1500A can include seven of the battery modules 1400 connected to one another. The power source 1500A may, for example, have a maximum power output between 1 KW and 60 kW during operation, a maximum voltage output between 10 V and 120 V during operation, or a maximum current output between 100 A and 500 A during operation.

The power source 1500A can include a power source housing 1510 mechanically coupled to at least one of the battery modules. The power source housing 1510 can include an end cover 1512 that covers a side of the power source housing 1510. The power source housing 1510 can have a length of L 2, such as 3 mm, 5 mm, 10 mm, 15 mm, 20 mm, 25 mm, 30 mm, 40 mm, 50 mm or within a range defined by two of the foregoing values or another value greater or less than the foregoing values. The width and the height of the power source housing 1510 can match the length of L1 and the width of W of the battery module 1400.

The power source 1500A can include power source connectors 1520. The power source connectors 1520 can be used to electrically connect the power source 1500A to another power source, such as another of the power source 1500A.

FIG. 6B illustrates a power source 1500B that is similar to the power source 1500A of FIG. 6A but with the end cover 1512 and the upper battery module housings 1430 of the battery modules 1400 removed. Because the end cover 1512 has been removed, a circuit board assembly 1514 of the power source 1500B is now exposed. The circuit board assembly 1514 can be electrically coupled to the battery modules 1400. The circuit board assembly 1514 can additionally provide galvanic isolation (for instance, 2500 Vrms) for the power source 1500B with respect to any components that may be electrically connected to the power source 1500B. The inclusion of galvanic isolation in this manner may, for instance, enable grouping of the battery modules 1400 together so that isolation may be provided to the grouping of the battery modules 1400 rather than individual modules of the battery modules 1400 or a subset of the battery modules 1400. Such an approach may reduce the costs of construction because isolation can be expensive, and a single isolation may be used for multiple of the battery modules 1400.

FIG. 7 illustrates a group 1600 of multiple power sources 1500A of FIG. 6A arranged and connected for powering an aircraft, such as the aircraft 100 of FIGS. 1A and 1B. The multiple power sources 1500A of the group 1600 can be mechanically coupled to or stacked on one another. The multiple power sources 1500A of the group 1600 can be electrically connected in series or parallel with one another, such as by a first connector 1610 or a second connector 1620 that electrically connects the power source connectors 1520 of two of the multiple power sources 1500A. As illustrated in FIG. 7, the group 1600 can include 10 power sources (for instance, arranged in a 5 row by 2 column configuration). In other examples, a group may include a fewer or greater number of power sources, such as 2, 3, 5, 7, 8, 12, 15, 17, 20, 25, 30, 35, or 40 power sources.

The grouping of the multiple power sources 1500A to form the group 1600 or another different group may allow for flexible configurations of the multiple power sources 1500A to satisfy various space or power requirements. Moreover, the grouping of the multiple power sources 1500A to form the group 1600 or another different group may permit relatively easy or inexpensive replacement of one or more of the multiple power sources 1500A in the event of a failure or other issue.

FIG. 8A illustrates a perspective view of a nose 1700 of an aircraft, such as the aircraft 100 of FIGS. 1A and 1B, that includes multiple power sources 1710, such as multiple of the power source 1500A, for powering a motor 1720 that operates a propeller 1730 of the aircraft. The multiple power sources 1710 can be used to additionally or alternatively power other components of the aircraft. The multiple power sources 1710 can be sized and arranged to optimize a weight distribution and use of space around the nose 1700. The motor 1720 and the propeller 1730 can be attached to and supported by a frame of the aircraft by supports, which can be steel tubes, and connected by multiple fasteners, which be bolts with rubber shock absorbers. A firewall 1740 can provide barrier between the multiple power sources 1710 and the frame of the aircraft in the event of a first at the multiple power sources 1710. An enclosure composed of glass fiber, metal, or mineral composite can be around the multiple power sources 1710 to protect from water, coolant, or fire.

FIG. 8B illustrates a side view of the nose 1700 of FIG. 8A.

FIG. 9A illustrates a top view of a wing 1800 of an aircraft that includes multiple power sources 1810, such as multiple of the power source 1500A, for powering one or more components of the aircraft. The multiple power sources 1810 can be sized and arranged to optimize a weight distribution and use of space around the wing 1800. For example, the multiple power sources 1810 can be positioned within, between, or around horizontal support beams 1820 or vertical support beams 1830 of the wing 1800. A relay 1840 can further be positioned in the wing 1800 as illustrated and housed in a sealed enclosure. The relay 1840 may open if there is not a threshold voltage on a breaker panel or if a pilot opens breakers to shut down the multiple power sources 1810.

FIG. 9B illustrates a perspective view of the wing 1800 of FIG. 9A.

The battery packs in different portions of the airplanes, for example the battery packs in the wings and/or in the nose, may be connected serially and/or in parallel.

### Multi-Coil Motor Control

An electric or hybrid aircraft can be powered by a multi-coil motor, such as an electric motor, in which different coils of the motor power different phases of a modulation cycle for the motor.

As can be seen from FIG. 10, a motor 1910 can include four different field coils (sometimes also referred to as coils) for generating a torque on a rotor of the motor 1910. The different field coils can include a first field coil 1902, a second field coil 1904, a third field coil 1906, and a fourth field coil 1908. Each of the different field coils can be independently powered by one or more controllers. The first field coil 1902, the second field coil 1904, the third field coil 1906, and the fourth field coil 1908 can be respectively powered by a first controller 1912, a second controller 1914, a third controller 1916, and a fourth controller 1918. One or more of the first controller 1912, the second controller 1914, the third controller 1916, and the fourth controller 1918 may be the same controller.

### Example Implementations of the Battery Monitoring System

A battery monitoring system is disclosed for monitoring and transmitting parameters relating to the state of a battery pack to a driver or pilot of an electric vehicle. The battery monitoring system can include a first battery monitoring circuit and a second redundant battery monitoring circuit. The first battery monitoring circuit can include multiple battery management systems (BMSs). Each BMS can manage and monitor a different subset of battery cells in the battery pack. The first battery monitoring circuit can include a digital communication bus to provide first warning signals to a driver or pilot of the vehicle in case of dysfunction of the battery pack. The second battery monitoring circuit can redundantly monitor the battery pack to provide at least one second warning signal to the driver or pilot of the vehicle in case of dysfunction of the battery pack. The second battery monitoring circuit may include only analog or combinational logic electronic components.

An electrical powering system is disclosed that can be used in an electric aircraft for powering a driving thrust-generating propeller or a lift-generating rotor. The electrical powering system can include: at least one motor; a first battery pack including high energy-density, low power battery cells; a second battery pack including low energy-density, high power battery cells; a circuit including a controller for powering said at least one motor from at least one of said battery packs and for generating motor driving signals for driving said at least one motor; wherein the electrical powering system is configured to charge said second battery pack from said first battery pack.

An electrical powering system is disclosed that can be used in an electric aircraft for powering a driving thrust-generating propeller or a lift-generating rotor. The electrical powering system can include: at least one motor; a first battery pack including high energy-density, low power battery cells; a second battery pack including low energy-density, high power battery cells; and a circuit comprising a controller for powering said at least one motor from at least one of said battery packs and for generating motor driving signals for driving said at least one motor. The electrical power system is configured to charge said first battery pack or said second battery pack from at least one of the at least one motor operating as generator.

The electrical powering system of the preceding paragraph can include one or more of the following features: The electrical powering system can charge one second battery pack from at least one of the at least one motor operating as generator.

### Example Implementations of Insulation Fault Detection Device, the Electrical Power Supply System And Elements of the Method for Detecting an Insulation Fault

FIGS. 11A to 11C illustrate an insulation fault detection device 40 and related signals according to the prior art. The threshold detection module 41 and the filtering module 43, as illustrated in FIG. 11A are embodied as analog circuit.

The insulation fault detection device 40 comprises the threshold detection module 41 and the filtering module 43. The threshold detection module 41 provides at the output end a raw failure detection signal R(T) which is fed into the filtering module 43 at the input end. The threshold detection module 41 is provided at the input end with two terminals for receiving voltage signals. One of the two terminals is connected to the negative DC potential DC− of an electrical power supply in the aircraft, for instance, the one illustrated in FIG. 13. The second terminal of the threshold detection module 41 is connected to a reference potential G, for example, the ground of the aircraft. Typically, most of the electrical or electronic devices located in the aircraft are referenced to the reference potential G.

The threshold detection module 41 comprises a voltage measurement circuit (not illustrated) to reduce the voltage signals to a lower level, such that they can be used by the threshold detection module 41. In an alternative implementation, the threshold detection module 41 can be configured to receive voltage measurement signals from a voltage sensor being external to the insulation fault detection device 40. The voltage sensor can provide the measurement signal in the form of a low voltage to the terminals of the threshold detection module 41. In this case, the voltage measurement circuit can be omitted, as the voltage measurement signal might be available as an analog voltage already.

The filtering module 43 is configured with an output terminal for providing a control signal S to a higher-level control device upon the detection of an insulation fault. The connection between the output terminal and the higher-level control device is, in this example, hard-wired connected. The hard-wired connection might be replaced by a communication bus, such as a safety communication bus, whereby the filtering module 43 can send signals over the bus to a higher-level control device.

FIG. 11B illustrates the signals of the insulation fault detection device 40 over time, in case of the insulation fault in the AC section, for instance, due to an insulation breakdown in a cable supplying the motor of 12 with AC power. In this example, the negative DC potential DC− is referenced to the second reference potential G₂, for example, by using the cable connection with an impedance as illustrated in FIG. 12.

The voltage measurement signal V_{DC-}-G illustrated in the top diagram represents the voltage (or potential difference) measured between the negative DC potential DC− and the second reference potential G₂. The voltage measurement signal V_{DC-}-G comprises a plurality of consecutive pulses, whereby the pulse period may correspond to the switching frequency of the motor converter, as illustrated in the electrical power supply system of FIG. 13. The pulses as illustrated, are generated by semiconductors of the motor controller under operation, as they alternately apply the positive or negative DC potential DC−, DC+ to the respective phase of the motor. This can include the phase being affected by the loss of isolation leading to have the chassis being alternatively connected to DC+ and DC−. However, the voltage measurement signal V_{DC-}-G waveform can differ from the presented waveform in case the electrical power supply system is configured differently.

The threshold detection module 41 provides the raw failure detection signal R, as illustrated in the centre diagram of the figure, dependent on the threshold T, as set and illustrated in the top diagram. After receiving a couple of pulses, the filtering module 43 sets the control signal S, as illustrated in the bottom diagram of the said figure. This indicates that an insulation fault was detected and a higher-level control device is notified. However, the detection depends on the absolute value of the voltage measurement signal V_{DC-}−G. If the absolute value is below the threshold T, the control signal S can be set by the filtering module 43, which indicates for a not illustrated downstream safety device the detection of an insulation fault. This disadvantage becomes apparent when moving to FIG. 11C.

FIG. 11C also illustrates the signals of the insulation fault detection device 40 over time, but the negative DC potential DC− is being referenced to the first reference potential G1. This might occur when the electrical power supply system differs in its configuration, in particular with respect to the configuration as illustrated in FIG. 12, or the voltage signals connected to the input terminals of the threshold detection module 41 as of FIG. 11A have been interchanged.

As it can be noticed in FIG. 11C in the top diagram, the voltage measurement signal V_{DC-}-G is negative, such that the threshold detection module 41 as of FIG. 11A does not output the raw detection signal R, because the signal is below the threshold T (see center diagram). Consequently, and as can be noticed in the bottom diagram, the control signal S is not set, and the insulation fault is not indicated. One might argue that a solution to this problem would be to create an absolute value of the voltage measurement signal V_{DC-}-G, such that it becomes positive, but the control signal S would still be dependent on the absolute value and in case of a weak or buried signal, the result would remain the same. On the other hand, when using the absolute value, the voltage measurement signal V_{DC-}-G would constantly be above the threshold T, probably triggering a false alarm. In conclusion, the main problem with the solution known from the prior art is that the insulation fault detection device 40 must be adapted to the aircraft configuration. The same insulation fault detection device 40 cannot be used when one of the DC potentials DC+, DC− is referenced differently.

FIG. 12 illustrates an electrical power supply system with an electrical source in the form of a battery 10. The battery outputs in this example a DC voltage V_{DC} with 1000V. This DC voltage V_{DC} is provided by battery cells (or battery modules) connected in series. The battery 10 is connected to the motor controller 20, and the motor controller 20 is configured to supply the motor 30 with electric energy. The motor controller 20 and the motor 30 are configured with an electrically conductive housing (dashed lines), for instance, made of metal, such as aluminium. The housing is connected to the reference potential G via a cable connection. The insulation fault detection device 40 is illustrated as an insulated component, but it can be comprised in or being a part of the battery 10, the motor controller 20 or the motor 30, or elsewhere. An electrical connection, comprising the impedance 4, connects the positive DC potential DC+, the negative DC potential DC−, or the neutral potential DC0 (also referred to as the third DC potential) to the reference potential G. Other intermediate potentials (not referenced) apparent in the battery 10, due to the series connection of battery cells, might be alternatively connected via the impedance 4 to the reference potential G. Depending to which DC potential the reference potential G is referenced, a different notation is used, and the use of dotted lines illustrates this. For instance, in case the positive DC potential DC+ is referenced to the reference potential, the notation G1 is used for further reference.

The insulation fault detection device 40, on the other hand, is connected in this example to the negative DC potential DC− and to the reference potential G with its input terminals, in the order as illustrated. A skilled person might notice that the voltage signals determinable at the input terminals of the insulation fault detection device 40 and in case of the insulation fault, always depend on the referenced DC potential. The insulation fault detection device 40 can also be connected to a different than the negative DC potential DC− , such as a different DC potential somewhere else comprised in the electrical system. Hower, one input terminal of the insulation fault detection device 40 always needs to be connected to the reference potential G.

Independently from the corresponding insulation failure scenario, a re-configuration of the potential reference might cause voltage signals of a different shape or polarity. Obviously, and as set out before, the insulation fault detection device according to the prior art is not suitable to cope with different configurations of the power supply system without adapting the threshold specifically.

FIG. 13 illustrates typical insulation fault scenarios in a motor controller 20 and a motor 30 connected thereto. The motor controller 20 comprises a DC voltage link with a series connection of two capacitors 22, 23, acting as common-mode filtering capacitors. The main DC link capacitor for buffering the electrical energy is not illustrated for the sake of simplicity. At the point of the series connection, the capacitors are connected to the reference potential G, which can be achieved with a simple cable connection to the conductive housing (illustrated with dashed lines). The metallic housing of the motor controller 20, in return, also is connected to the reference potential G. The DC voltage link in the said configuration provides the advantage of reducing electromagnetic interference. The motor controller 20 is configurated with a positive rail, carrying the voltage with the positive DC potential DC+, and a negative rail, carrying the voltage with the negative DC potential DC−. The motor controller 20 is connected at the input end to the battery as of FIG. 12, whereby the positive and the negative rail carry the current supplied by the battery.

The connection between the motor controller 20 and the battery can be interrupted with the use of the power contactor 21 arranged in the positive and negative rail. The motor controller 20 also comprises a plurality of semiconductor elements 24, for instance, in the form of IGBTs, which can selectively connect the positive rail or the negative rail to the three supply lines 25 connecting the motor 30 to the motor controller 20.

The motor 30 comprises multiple stator windings 32 and corresponding input terminals 31 for receiving the AC currents or voltages from the motor controller 20. The motor 20 is also equipped with a temperature sensor 33 to determine the temperature of the stator windings 32. The rails, the three phase lines 25, and the semiconductor elements 24 are under normal operations insulated from the conductive housing of the motor controller 20, with the use of suitable insulating materials, and thus floating with respect to reference potential G.

The positive and the negative DC potential DC+, DC− are also insulated from each other or at least routed separately, and at least one of the DC potentials is insulated with respect to the reference potential G, even when being connected to the reference potential G via the cable connection including the impedance as of FIG. 12. Under normal operation, in the absence of an insulation fault, the input terminals 31, the stator windings 32 and the temperature sensor 33 are also insulated from the conductive housing (dashed lines).

The arrows illustrate examples of insulation faults leading to the fault current It. The fault current It can flow between the negative rail, or one of the three supply lines, and the conductive housing of the motor controller 20. A particular insulation fault scenario occurs when the capacitor 22 breaks (due to the fault of the dialect medium). In this scenario the positive DC potential DC+ comes into contact with the reference potential G.

Equivalent scenarios leading to the fault current It are illustrated with respect to the motor 30, wherein the fault current If flows from one of the input terminals 31 or one of the stator windings 32 to the conductive housing. A specific scenario is developed for the temperature sensor 33, as the AC voltage supplied by the motor controller to the stator windings can force an insulation breakdown in the temperature sensor 33. The temperature sensor 33 gets into contact with one of the stator windings 32, which will also cause the fault current If to flow.

All fault scenarios outlined in the paragraphs before can be detected with the insulation fault detection device according to the invention, but not with the insulation fault detection device according to the prior art as of FIG. 11A. However, and insulation fault directly apparent between the positive and the negative DC potential DC+, DC− can't be detected with the insulation fault detection device according to the invention.

FIGS. 14A to 14C illustrate the insulation fault detection device 40 and related signals according to one example of the invention. The threshold detection module 41, the high-pass filter 42, and the filtering module 43, as illustrated in FIG. 14A, are implemented in analog domain, whereby a measurement circuit, for example, makes use of further analog components (not shown).

The threshold detection module 41 provides at the output end the raw failure detection signal R(T), which is fed into the filtering module 43 at the input end. The threshold detection module 41 is provided at the input end with one terminal for receiving prefiltered voltage signal E, which is provided by the high-pass filter 42 at its output end. The high-pass filter 42 at its input end is connected at the first terminal to the negative DC potential DC− and with the second terminal to the reference potential G.

The high-pass filter 42 is configured as an analog first-order active high-pass filter, for cancelling a DC component that can be apparent in the measured potential difference determined between the two input terminals. If the input terminals are directly connected to the negative DC potential DC− and the reference potential G, it might be necessary to adjust the measured voltage to a lower signal level with the measurement circuit, such that the high-pass filter 42 can handle the high voltage or high potential difference accordingly.

The electrical power supply system to which the two input terminals of the high-pass filter 42 are connected is configured as illustrated in FIG. 12, whereby it doesn't matter which of the DC potentials is referenced to the reference potential using the connection comprising the impedance.

The input terminals of the high-pass filter 42 must not necessarily be directly connected to the negative DC potential DC− and the reference potential G. Instead a voltage sensor can be used to measure the potential difference, and the signal obtainable from the voltage sensor can be directly fed into the high-pass filter 42. The configuration of the filtering module 43 corresponds to the configuration of the filtering module 43 as of FIG. 11A.

FIG. 148 illustrates the signals of the insulation fault detection device 40 over time, in case of the insulation fault between the negative DC potential DC− and the reference potential G, for instance, due to an insulation breakdown in a cable. In this example, the negative DC potential DC− is referenced to the second reference potential G2, for example, by using the cable connection with an impedance as illustrated in FIG. 12.

The voltage measurement signal V_{DC-}−G determined by the high-pass filter 42 is illustrated in the top diagram and represents the voltage (or potential difference) measured between the negative DC potential DC− and the reference potential G. The voltage measurement signal V_{DC-}−G comprises a plurality of consecutive pulses, whereby the pulse period may correspond to the switching frequency of the motor converter, as illustrated in the electrical power supply system of FIG. 13. Again, the pulses are generated by switching the semiconductors of the motor controller.

The high-pass filter 42 provides the prefiltered voltage signal E to the threshold detection module 41. It can be noticed in the second diagram from the top that the prefiltered voltage signal E comprises consecutive spike signals, which can be expressed as the step response of the analog filter circuit comprised in the high-pass filter 42. The spikes can be positive or negative.

Dependent on the two thresholds T1, T2 set, the threshold detection module 41 outputs corresponding raw failure detection signals R (illustrated in the third diagram from the top). In contrast to the solution known from the prior art, the raw failure detection signal R depends on the detection of the rising edge and the falling edge of the voltage measurement signal V_{DC-}−G and not on the absolute value (threshold) of the said the voltage measurement signal V_{DC-}−G.

The filtering module 43 sets the control signal S, as illustrated in the bottom diagram of the said figure, after the detection of a couple of consecutive edges. This indicates to a higher-level control device that one insulation fault has been detected.

In case only one of the two thresholds T1, T2 is set, the detection can be calibrated to only detect the raising or the falling edge of the prefiltered voltage signal E. The filtering module 43 can also be configured to set the control signal S after the detection of one raising or one falling edge, or after the detection of one raising and one falling edge. In conclusion, the failure can be detected by detecting positive and negative excursion, detecting positive or negative excursion, or recovering the prefiltered voltage signal E and detecting positive excursion.

FIG. 14C illustrates the signals of the insulation fault detection device 40 over time, in case of an insulation fault between the negative DC potential DC− and the reference potential G, for instance, due to an insulation breakdown in a cable. In this example, the negative DC potential DC− is referenced to the first reference potential G₁ by using the cable connection with the impedance as illustrated in FIG. 12.

The voltage measurement signal V_{DC-}−G now provides negative voltage pulses to the highpass-filter 42, because the negative DC potential is referenced differently. However, the control signal S is set after a couple of voltage pulses. The remaining signals correspond to the signals of FIG. 148, which in return, makes the insulation fault detection device 40 interoperable between different configurations of the electrical supply system. Furthermore, the insulation fault detection device 40 of FIG. 14A is enabled to detect all insulation fault scenarios, as explained in FIG. 13.

### Additional Features and Terminology

Although examples provided herein may be described in the context of an aircraft, such as an electric or hybrid aircraft, one or more features may further apply to other types of vehicles usable to transport passengers or goods. For example, the one or more futures can be used to enhance construction or operation of automobiles, trucks, boats, submarines, spacecrafts, hovercrafts, or the like.

Many other variations than those described herein will be apparent from this disclosure. For example, depending on the embodiment, certain acts, events, or functions of any of the algorithms described herein can be performed in a different sequence, can be added, merged, or left out altogether (for example, not all described acts or events are necessary for the practice of the algorithms). Moreover, in certain embodiments, acts or events can be performed concurrently, for instance, through multi-threaded processing, interrupt processing, or multiple processors or processor cores or on other parallel architectures, rather than sequentially. In addition, different tasks or processes can be performed by different machines or computing systems that can function together.

Unless otherwise specified, the various illustrative logical blocks, modules, and algorithm steps described herein can be implemented as electronic hardware, computer software, or combinations of both. To clearly illustrate this interchangeability of hardware and software, various illustrative components, blocks, modules, and steps have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

Unless otherwise specified, the various illustrative logical blocks and modules described in connection with the embodiments disclosed herein can be implemented or performed by a machine, a microprocessor, a state machine, a digital signal processor (DSP), an application specific integrated circuit (ASIC), a FPGA, or other programmable logic device, discrete gate or transistor logic, discrete hardware components, or any combination thereof designed to perform the functions described herein. A hardware processor can include electrical circuitry or digital logic circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. A computing environment can include any type of computer system, including, but not limited to, a computer system based on a microprocessor, a mainframe computer, a digital signal processor, a portable computing device, a device controller, or a computational engine within an appliance, to name a few.

Unless otherwise specified, the steps of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile. The processor and the storage medium can reside in an ASIC.

Conditional language used herein, such as, among others,“ can,” “might,” “may,” “e.g.,” and the like, unless specifically stated otherwise, or otherwise understood within the context as used, is generally intended to convey that certain embodiments include, while other embodiments do not include, certain features, elements or states. Thus, such conditional language is not generally intended to imply that features, elements or states are in any way required for one or more embodiments or that one or more embodiments necessarily include logic for deciding, with or without author input or prompting, whether these features, elements or states are included or are to be performed in any particular embodiment. The terms “comprising,” “including,” “having,” and the like are synonymous and are used inclusively, in an open-ended fashion, and do
not exclude additional elements, features, acts, operations, and so forth. Also, the term “or” is used in its inclusive sense (and not in its exclusive sense) so that when used, for example, to connect a list of elements, the term “or” means one, some, or all of the elements in the list. Further, the term “each,” as used herein, in addition to having its ordinary meaning, can mean any subset of a set of elements to which the term “each” is applied.

1.-21. (canceled)

22. An insulation fault detection device for detecting insulations faults in an electrical power supply system of an electrically or hybrid driven aircraft, wherein the electrical power supply system being configured with a DC section and an AC section, wherein the insulation fault detection device includes:
an input terminal configured to receive a measurement signal, which is a voltage measurement signal, from a voltage sensor, preferably external to the insulation fault detection device;
an output terminal arranged to provide a signal for indicating an insulation fault;
characterized in that; and
a processor coupled to the input and output terminal, and wherein the processor is configured to:
detect frequency and/or a slope of an AC voltage component comprised in the measurement signal of the measurement signal; and
set the signal at the output terminal depending on the detected frequency and/or a slope of an AC component comprised in the measurement signal, wherein the AC voltage component comprised in the voltage measurement signal is a signal having a predefined shape, and wherein the slope corresponds to an edge of the signal and wherein the signal at the output terminal is set upon the detection of the edge of the signal.

23. The insulation fault detection device of claim 22, wherein the AC voltage component comprised in the voltage measurement signal is a signal having a rectangular shape, wherein the slope corresponds to an edge of the rectangular signal.

24. The insulation fault detection device of claim 22, wherein the signal at the output terminal is set upon the detection of a series of edges, wherein the series preferably comprises more than 3, preferably more than 5, most preferably more than 10 edges.

25. The insulation fault detection device of claim 22, wherein the voltage measurement signal comprises the AC voltage component and a DC voltage component, and wherein the processor is configured to be sensitive to the AC voltage component only.

26. The insulation fault detection device of claim 25, wherein the processor comprises a filter connected to the input terminal and configured to cancel the DC voltage component comprised in the voltage measurement signal.

27. An electrical power supply system for an electrically or hybrid driven aircraft comprising:
an insulation fault detection device;
a voltage sensor;
an electrical source configured with a first and a second output for supplying a DC voltage, the DC voltage having a first and a second DC potential;
a load configured with an input end and an output end, wherein the input end is connected to the first and the second output of the electrical source, and the output end is connected to an AC consumer;
an electric connection permanently connecting one of the DC potentials to a reference potential of the aircraft, and wherein the electrical source and the load are configured to insulate the DC potentials from each other, wherein
the voltage sensor is electrically connected to one of the DC potentials and the reference potential for determining a potential difference between one of the DC potentials and the reference potential.

28. The electrical power supply system of claim 27, wherein the electrical source is configured with a third output and provides a third DC potential, wherein the third DC potential ranges between the first and the second DC potential.

29. The electrical power supply system of claim 28, wherein the electric connection is arranged to permanently connect or reference the third DC potential to the reference potential.

30. The electrical power supply system of claim 27, wherein the electric connection comprises an impedance, wherein the impedance is configured with an ohmic resistance greater than 400 kω, preferably greater than or equal to 1 Mω.

31. The electrical power supply system of claim 27, wherein the load comprises a motor controller and a motor for propelling the aircraft, wherein an input end of the motor controller corresponds to the input end of the load, and wherein the AC consumer corresponds to the motor connected to the output end.

32. The electrical power supply system of claim 31, wherein the motor controller comprises a switch configured to interrupt the connection between the input end and the electrical source.

33. The electrical power supply system of claim 31, wherein the motor controller comprises a DC link connected to the first and second DC potential at the input end, wherein the DC link comprises a series connection of a first and a second capacitor with a center tap, wherein the center tap is connected to the reference potential via a further electrical connection.

34. A method for detecting an insulation fault in an electrical power supply system, comprising:
measuring a potential difference between one DC potential and a reference potential for obtaining a voltage measurement signal;
detecting a slope of an AC voltage component comprised in the voltage measurement signal wherein the AC voltage component comprised in the voltage measurement signal is a signal having a predefined shape, wherein the slope corresponds to an edge of the signal;
signalling the detection of the slope for indicating an insulation fault, wherein the signalling is carried out upon the detection of the edge of the signal.

35. The method for detecting an insulation fault of claim 34, further comprising cancelling the DC voltage component comprised in the voltage measurement signal.

36. The method for detecting an insulation fault of claim 34, wherein the AC voltage component comprised in the voltage measurement signal is the signal having a rectangular shape, wherein the slope corresponds to the edge of the rectangular signal.

37. The method for detecting an insulation fault claim 36, wherein the signalling is carried out upon the detection of a series of edges, wherein the series preferably comprises more than 3, preferably more than 5, most preferably more than 10 edges.
